(19) United States
(12) Patent Application Publication
(10) Pub. No.: US 2023/0083359 A1
(43) Pub. Date: Mar. 16, 2023

(54) ELECTRONIC APPARATUS WITH AIRFLOW STRUCTURE AND MOISTURE INTRUSION MITIGATION

(71) Applicant: UBICQUIA, INC., Fort Lauderdale, FL (US)

(72) Inventors: Claudio Santiago Ribeiro, Evanston, IL (US); Cesar Eduardo Nunez, Miramar, FL (US)

(21) Appl. No.: 17/476,359

(22) Filed: Sep. 15, 2021

(51) Int. Cl. H05K 5/02

(52) U.S. Cl. CPC H05K 5/0213

(57) ABSTRACT

An electronic apparatus includes a housing, at least one air intake port, an exhaust port, an air duct, and electronic circuitry. The housing has top and bottom portions and one or more sidewalls interconnecting the top and bottom portions. The air intake port(s) is configured in the bottom portion of the housing. The air exhaust port is configured in a sidewall of the housing and positioned between the top and bottom portions of the housing. The air duct is positioned proximate the air exhaust port. The air duct includes at least one wall defining an air entry port and an air exit port. The air exit port is aligned generally with the air exhaust port. The air entry port is positioned closer to the top portion of the housing than is the air exit port. The circuitry is positioned between the bottom portion of the housing and the air duct.

### TECHNICAL FIELD

The present disclosure relates generally to electronic devices that may require air exhaust and are mounted outdoors. More particularly, but not exclusively, the present disclosure relates to an electronic apparatus that is outdoor-mountable and provides air exhaust while mitigating moisture intrusion.

### BACKGROUND

As is known, many different types of electronic devices, such as timers, environmental sensors, or monitoring devices, may be mounted outdoors and, therefore, exposed to rain, snow, and other moisture. Such devices are typically housed in structures that are fully enclosed to prevent moisture intrusion, but poorly suited for providing adequate ventilation to facilitate the removal of heat generated by such devices or for permitting a flow of air generally through the devices. The outdoor environment in which the electronic devices are installed may also contribute to the overall thermal stresses inflicted on such devices. Simply adding ventilation holes to assist with air flow and heat removal may expose the devices to water intrusion and resultant malfunction.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of an approach to solving the particular problem, which, in and of itself, may also be inventive.

### SUMMARY

According to one exemplary embodiment of the present disclosure, an electronic apparatus includes a housing, at least one air intake port, an exhaust port, an air duct, and electronic circuitry. The housing has top and bottom portions and one or more sidewalls interconnecting the top and bottom portions. The air intake port(s) is configured in the bottom portion of the housing. The air exhaust port is configured in a sidewall of the housing and positioned between the top and bottom portions of the housing. The air duct is positioned proximate the air exhaust port. The air duct includes at least one wall defining an air entry port and an air exit port. The air exit port is aligned generally with the air exhaust port. The air entry port is positioned closer to the top portion of the housing than is the air exit port. The electronic circuitry is positioned within the housing between the bottom portion of the housing and the air duct.

According to an alternative embodiment, the electronic apparatus may further include at least one fan operable to force air from the at least one air intake port toward the top portion of the housing. The electronic apparatus may also include one or more sensors mounted on or within the housing. Still further, the electronic circuitry of the electronic apparatus may include at least a plurality of environmental sensors, such as an ozone sensor, a nitrous oxide sensor, a sulfur dioxide sensor, a carbon monoxide sensor, a particulate matter sensor, and/or a microphone. The electronic circuitry may also include a digital addressable lighting interface (DALI) module.

According to a further embodiment, the air duct may be integrated into the sidewall of the housing such that the exit port of the air duct aligns with the air exhaust port. Additionally or alternatively, the air exhaust port may be configured in the sidewall of the housing at a position at least two-thirds the length of the sidewall as measured from an intersection of the sidewall and the bottom portion of the housing.

According to yet another embodiment, the top portion of the housing may be slanted away from the sidewall and the bottom portion of the housing so as to channel air flow toward the air entry port of the air duct. For example, the top portion of the housing may be slanted at an angle in a range of about 15 degrees to about 60 degrees relative to an axis orthogonal to the sidewall. Additionally or alternatively, the bottom portion of the housing may be slanted away from the sidewall and the top portion of the housing.

According to a further embodiment, the electronic apparatus may further include at least a second air exhaust port configured in a sidewall of the housing and positioned between the bottom portion of the housing and the top portion of the housing. In such a case, the electronic apparatus may include at least a second air duct, where each air duct is positioned inside the housing proximate a respective air exhaust port. In yet another embodiment, two or more air exhaust ports may be configured in the same sidewall of the housing. In a further embodiment, a hydrophobic mesh may be inserted within one or more of the air exhaust ports.

According to yet another embodiment, an electronic apparatus includes a housing, at least one air intake port, an exhaust port, an air duct, and electronic circuitry. According to this embodiment, the housing has a slanted top portion, a bottom portion, and one or more sidewalls interconnecting the top and bottom portions. The air intake port(s) is configured in the bottom portion of the housing. The air exhaust port is configured in a sidewall of the housing and positioned between the top and bottom portions of the housing. The air duct is integrated into an inside surface of the sidewall of the housing proximate the air exhaust port. The air duct includes at least one wall defining an air entry port and an air exit port. The air exit port is aligned generally with the air exhaust port. The air entry port is positioned closer to the top portion of the housing than is the air exit port. The electronic circuitry is positioned within the housing between the bottom portion of the housing and the air duct.

According to a further embodiment, the electronic apparatus may further include at least a second air exhaust port integrated into the inside surface of the sidewall of the housing and positioned between the bottom portion of the housing and the top portion of the housing. In such a case, the electronic apparatus may include at least a second air duct, where each air duct is positioned inside the housing proximate a respective air exhaust port. In yet another embodiment, the electronic apparatus may include a fan operable to force air from the at least one air intake port toward the top portion of the housing and/or the electronic circuitry may include a plurality of environmental sensors. In a further embodiment, a hydrophobic mesh may be inserted within one or more of the air exhaust ports.

According to still another embodiment, an electronic apparatus includes a housing, at least two air intake ports, at least two air exhaust ports, at least two air ducts, and electronic circuitry. According to this embodiment, the housing has a top portion, a bottom portion, and one or more sidewalls interconnecting the top and bottom portions. The air intake ports are configured in the bottom portion of the housing. The air exhaust ports are configured in a sidewall of the housing and positioned between the top and bottom portions of the housing. The air ducts are located inside the housing, with each air duct being positioned proximate a respective air exhaust port. Each air duct includes at least one wall defining an air entry port and an air exit port. The air exit port of an air duct is aligned generally with the air duct's associated air exhaust port. The air entry port of an air duct is positioned closer to the top portion of the housing than is the air exit port of the air duct. The electronic circuitry is positioned within the housing between the bottom portion of the housing and the air ducts. According to a further embodiment, the top portion of the housing may be slanted away from the sidewall and the bottom portion of the housing so as to channel air flow toward air entry ports of the air ducts.

In some embodiments, an electronic apparatus includes a housing enclosure having sidewalls, at least one air intake port configured at a bottom portion of the sidewalls, and at least one air exhaust port configured near a top portion of the sidewalls of the apparatus. The housing enclosure is arranged and configured to force air from the at least one air intake port and out the at least one air exhaust port. The electronic apparatus further includes at least one cup-like structure arranged and constructed on an inside portion of the housing enclosure proximate the at least one air exhaust port to capture and contain any moisture intruding through housing enclosure and to further guide air out of the at least one exhaust port. In some embodiments, the at least one air exhaust port can further include a hydrophobic mesh. In some embodiments, the electronic apparatus includes a plurality of environmental sensors mounted on a substrate within the housing enclosure.

In some embodiments, the electronic apparatus further includes at least one fan to force air from the at least one air intake portion and out the at least one air exhaust port. In some embodiments multiple fans are used and some fans could be integrated into some of the components of the electronic device such as in one or more environmental sensors. In some embodiments, the electronic apparatus can further include one or more external sensors mounted on the housing enclosure such as a temperature sensor and a humidity sensor or a combination thereof.

In some embodiments, the plurality of environmental sensors are mounted on the substrate having two or more sensors among a ozone sensor, a nitrous oxide sensor, a sulfur dioxide sensor, a carbon monoxide sensor, a particulate matter sensor or a microphone. In some instances, the substrate can be a printed circuit board, a flexible substrate or even an inner portion of the housing enclosure itself. In some embodiments the electronic apparatus can further include a DALI module mounted on the substrate.

In some embodiments the electronic apparatus is an environmental sensor device mounted on a utility pole. Notwithstanding the examples provided herein, the electronic device is not limited to an environmental sensor and not necessarily limited to being mounted on a utility pole, but can be any electronic device mounted on or some cases within a streetlight, a light pole, an LED board, an LED luminaire device, a bracket, a street sign, a highway sign, a bus stop shelter, an ATM, a phone booth, a building, an HVAC unit, a mailbox, a billboard, a light, a parking sign, a stop light, a speed limit sign, a solar cell, a crosswalk sign, a tunnel, a utility box, a water tower, a crane, a radio antenna tower, a store, an awning, a roof, a highway overpass, or a parking pay station as a non-exhaustive example.

In some embodiments, the housing enclosure can include a upwardly slanted top wall where the at least one cup-like structure forms a channel below the upwardly slanted top wall of the housing enclosure causing air flow to flow down from the upwardly slanted top wall and out of the at least one air exhaust port where at least a portion of the channel resides above a level of the at least one air exhaust port which is near the top portion of the sidewalls of the apparatus. In some embodiments the at least one cup-like structure is integrally formed on an internal portion of the housing enclosure.

In some embodiments, the electronic apparatus further includes at least one fan mounted inside the housing enclosure proximate the at least one air intake port, where the fan is configured to suck cool air in through at least one air intake port and force such air over heat sources and toward a top portion of the housing enclosure and toward the at least one air exhaust port.

In some embodiment, the electronic apparatus is an environmental sensor apparatus having a housing enclosure having sidewalls on one or more housing enclosure members including an upwardly slanted top wall and a downwardly slanted bottom wall on one of the one or more housing enclosure members, at least one air intake port configured at a bottom portion of the sidewalls, and at least one air exhaust port configured near a top portion of the sidewalls of the apparatus where the housing enclosure is arranged and configured to force air from the at least one air intake port and out the at least one air exhaust port. The environmental sensor apparatus can further include at least one channel structure arranged and constructed on an inside portion of the housing enclosure proximate the at least one air exhaust port to capture and contain any moisture intruding through housing enclosure where the channel structure includes a portion residing at a level above the at least one exhaust port. In some embodiments, the environmental sensor apparatus includes a plurality of environmental sensors mounted on a substrate within the housing enclosure. In some embodiments, the substrate is a printed circuit board and the plurality of environmental sensors mounted on the substrate include any combination of two or more among a ozone sensor, a nitrous oxide sensor, a sulfur dioxide sensor, a carbon monoxide sensor, a particulate matter sensor, and a microphone.

In some embodiments, the environmental sensor apparatus includes at least one fan to force air from the at least one air intake portion and out the at least one air exhaust port. In some embodiments, the at least one air exhaust portion includes at least two air exhaust portions and the at least one air intake ports comprise at least two air intake portions.

In some embodiments, the environmental sensor apparatus further includes at least one or more processors mounted on a shielded portion of the substrate and wherein the plurality environmental sensors reside on an unshielded portion of the substrate.

In some embodiments, an environmental sensor apparatus includes a housing enclosure having sidewalls including at least an upwardly slanted top wall, at least two air intake ports configured at a bottom portion of the sidewalls, and at least two air exhaust ports configured near the upwardly slanted top wall, where the housing enclosure is arranged and configured to force air from the at least two air intake ports and out the at least two air exhaust ports. The environmental sensor apparatus can further include at least one channel structure arranged and constructed on an inside portion of the housing enclosure proximate the at two air exhaust ports to capture and contain any moisture intruding through housing enclosure where the at least one channel structure includes a portion residing at a level above the at least one exhaust port. In some embodiments, the environmental sensor apparatus further includes a plurality of environmental sensors mounted on a substrate within the housing enclosure including at least a carbon monoxide sensor and a particulate matter sensor.

In some embodiments the plurality of environmental sensors mounted on the substrate further includes a sulfur dioxide sensor, a nitrous dioxide sensor, an ozone sensor, and a microphone and where the environmental sensor apparatus further includes a temperature sensor and a humidity sensor mounted outside of the housing enclosure.

### BRIEF DESCRIPTION OF THE DRAWINGS

Non-limiting and non-exhaustive embodiments are described with reference to the following drawings, wherein like reference numerals refer to like parts, components, or elements throughout the various views, unless otherwise specified. The sizes and relative positions of elements in the drawings are not necessarily drawn to scale. For example, the shapes of various elements are selected, enlarged, and positioned to improve drawing legibility. The particular shapes of the elements as drawn have been selected for ease of recognition in the drawings.

FIG. 1 illustrates a front perspective view of an electronic apparatus in accordance with one exemplary embodiment of the present disclosure.

FIG. 2 illustrates a rear perspective view of the electronic apparatus of FIG. 1.

FIG. 3 illustrates an exploded view of the electronic apparatus of FIG. 1 showing exemplary electronic circuitry and other exemplary components in accordance with an embodiment of the present disclosure.

FIG. 4 illustrates an exemplary arrangement of electronic circuit components used within the exemplary electronic apparatus of FIG. 1.

FIG. 5 illustrates an exemplary back or rear view of a substrate on which the electronic circuitry of FIG. 4 is mounted in accordance with another embodiment of the present disclosure.

FIG. 6 illustrates an electrical block diagram of a combined temperature and humidity sensor module for mounting to or within the housing of electronic apparatus of FIG. 1 in accordance with another exemplary embodiment of the present disclosure.

FIG. 7 is an internal view of a front housing enclosure member of the exemplary electronic apparatus of FIG. 1.

FIG. 8 is an external view of the front housing enclosure member of FIG. 7.

FIG. 9 is a view within the exemplary electronic apparatus of FIG. 1 showing assembly of electronic circuitry within the electronic apparatus' housing between a bottom portion of the housing and one or more air ducts, in accordance with an alternative embodiment of the present disclosure.

FIG. 10 is a side view of the exemplary electronic apparatus of FIG. 1.

FIG. 11 illustrates another rear perspective view of the exemplary electronic apparatus of FIG. 1.

FIG. 12 is a side cutaway view of the exemplary electronic apparatus of FIG. 1 illustrating an exemplary airflow pattern or path in and through a housing of the electronic apparatus in accordance with an embodiment of the present disclosure.

FIG. 13 is an enlarged partial view of the side cutaway view of FIG. 12 further illustrating the airflow path through the housing of the exemplary electronic apparatus of FIG. 1.

FIG. 14 is an electrical block diagram of exemplary electronic circuitry for inclusion within an electronic apparatus in accordance a further alternative embodiment of the present disclosure.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. Also in these instances, well-known structures may be omitted or shown and described in reduced detail to avoid unnecessarily obscuring descriptions of the embodiments.

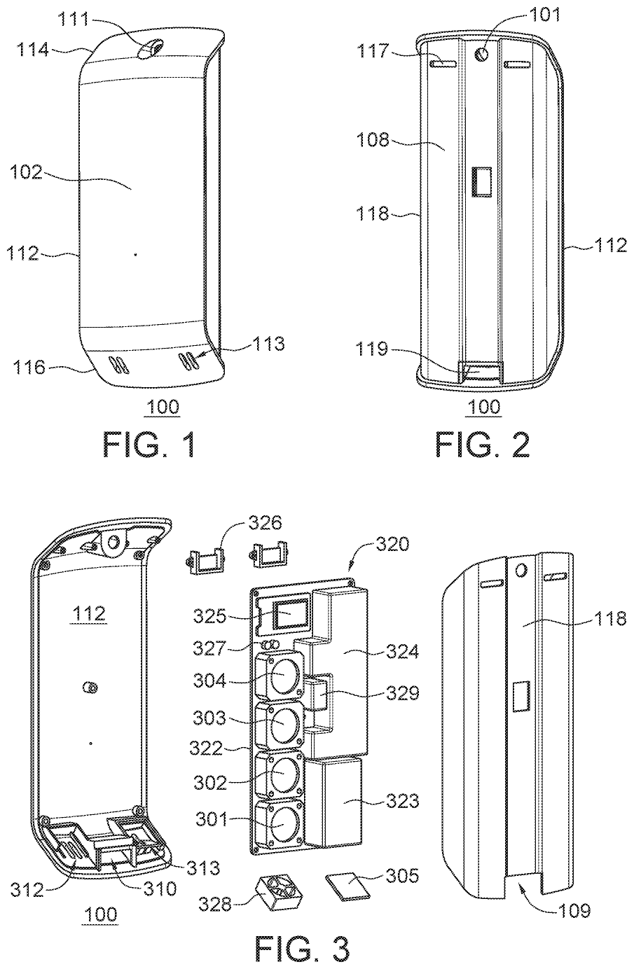

Referring to FIGS. 1-3, various views of an exemplary electronic product or apparatus 100 include a housing having one or more enclosure members (112, 118) having respective sidewalls (102 and 108), at least one air intake port 113 configured at a bottom portion 116 of the sidewalls, and at least one air exhaust port 117 configured near a top portion 114 of the sidewalls of the apparatus. The housing enclosure (112 and 118) is arranged and configured to force air from the at least one air intake port 113 and out the at least one air exhaust port 117. The electronic apparatus 100 further includes at least one cup-like structure 326 arranged and constructed on an inside portion of the housing enclosure (as shown in the exploded view of FIG. 3) proximate to the at least one air exhaust port 117 to capture and contain any moisture intruding through housing enclosure and to further guide air out of the at least one exhaust port 117. In some embodiments, the at least one air exhaust port can further include a hydrophobic mesh 1399 (see FIG. 13). In some embodiments, the electronic apparatus includes a plurality of environmental sensors mounted 301, 302, 303, and 304 on a substrate 322 of an assembly 320 within the housing enclosure.

Optionally, the electronic apparatus 100 and corresponding housing members 112 and 118 can both include an aperture or hole 111 and 101 respectively on top portions of the housing members for purposes of mounting the electronic apparatus 100 to a wall using a screw or nail. Similarly, the housing members can form a bracket hook feature 119 as shown in FIG. 2. The bracket hook feature 119 can be formed by structure 310 in housing member 112 and cut-out 109 on housing member 118 when housing member 112 and housing member 118 are mated together to form the housing enclosure.

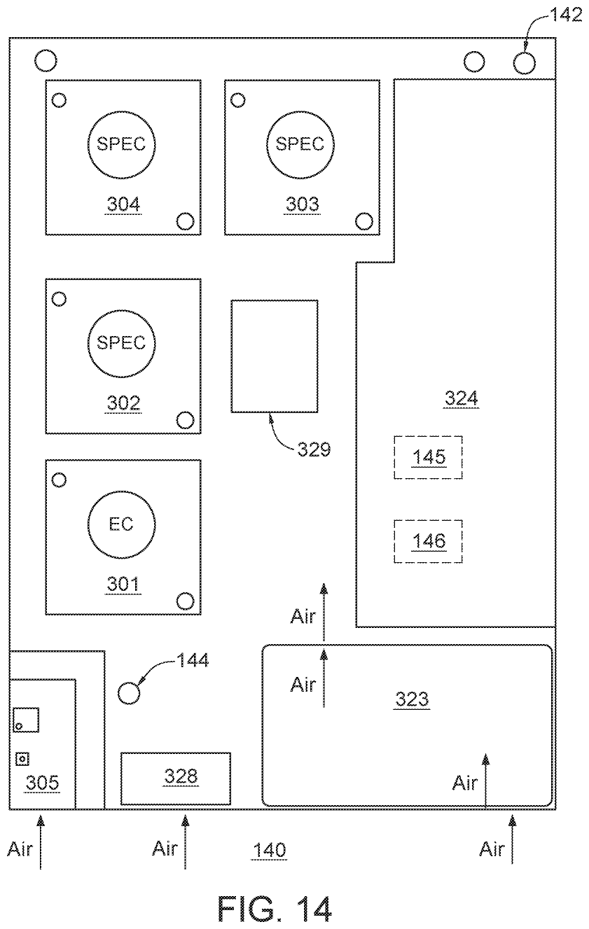

In some embodiments, the electronic apparatus further includes at least one fan 328 to force air from the at least one air intake port 113 and out the at least one air exhaust port 117. In some embodiments multiple fans are used and some fans could be integrated into some of the components of the electronic device such as in one or more environmental sensors (see discussion of PM sensor 323 with respect to FIG. 14). In some embodiments, the electronic apparatus 100 can further include one or more external sensors 305 mounted on the housing enclosure such as a temperature sensor and a humidity sensor or a combination thereof. The “external” sensors can still be mounted within the housing enclosure and yet have exposure to the ambient environment outside of the housing enclosure. In some embodiments, the fan 328 can be mounted in an area or a slot 312 and the external sensors 305 can be mounted in an area or a slot 313 of the housing member 112 as shown in FIGS. 3 and 9.

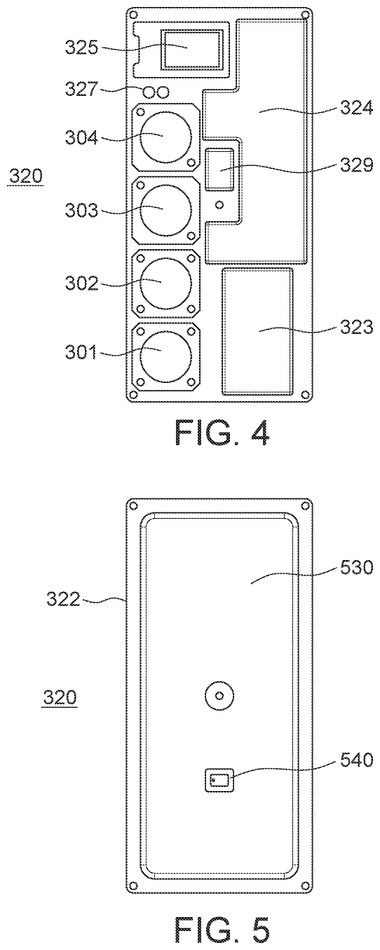

In some embodiments and with further reference to FIGS. 3, 4, and 5, the plurality of environmental sensors can be mounted on the substrate 322 having two or more sensors among an ozone sensor 304, a nitrous oxide sensor 303, a sulfur dioxide sensor 302, a carbon monoxide sensor 301, a particulate matter sensor 323 or a microphone 327. FIG. 4 illustrates a front view of the assembly or populated substrate 320. In some instances, the substrate 322 can be a printed circuit board, a flexible substrate or even an inner portion of the housing enclosure itself. In some embodiments the electronic apparatus can further include a digital addressable lighting interface (DALI) module 325 mounted on the substrate 320. The DALI module 325 uses a two-way communication protocol for building lighting applications and is used for communications between lighting control devices, such as electronic ballasts, brightness sensors or motion detectors and helps to manage networked lighting-control systems. In some embodiments, the substrate can further include a connector 329 such as a Molex™ connector and a noise keep out 324 mounted on the front side of the substrate 322. On a reverse side or backside of the substrate 322 as shown in in the assembly 320 of FIG. 5, the substrate 322 can further include a components' keep out 530 and a microphone 540. The noise keep out 324 and components' keep out 530 are used to provide isolation and mitigate signal interference among the various devices in the electronic apparatus 100.

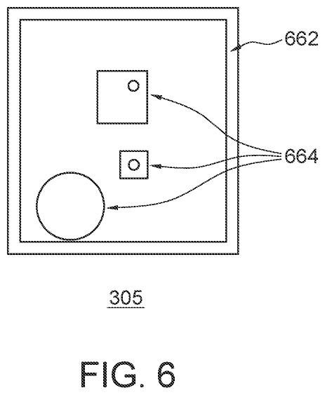

Referring to FIGS. 3 and 6, the external sensors 305 can be a module mounted on a substrate and further mounted on or in the slot 313 of the housing member 112 and sealed from other volumes within the housing enclosure using a seal surface 662. The external sensor 305 can include a plurality of sensors 664 which can include among any combination of a temperature sensor, a humidity sensor, a pressure sensor, and a microphone.

In some embodiments the electronic apparatus is an environmental sensor device mounted on a utility pole. Notwithstanding the examples provided herein, the electronic device is not limited to an environmental sensor and not necessarily limited to being mounted on a utility pole, but can be any electronic device mounted on or some cases within a streetlight, a light pole, an LED board, an LED luminaire device, a bracket, a street sign, a highway sign, a bus stop shelter, an ATM, a phone booth, a building, an HVAC unit, a mailbox, a billboard, a light, a parking sign, a stop light, a speed limit sign, a solar cell, a crosswalk sign, a tunnel, a utility box, a water tower, a crane, a radio antenna tower, a store, an awning, a roof, a highway overpass, or a parking pay station as a non-exhaustive example.

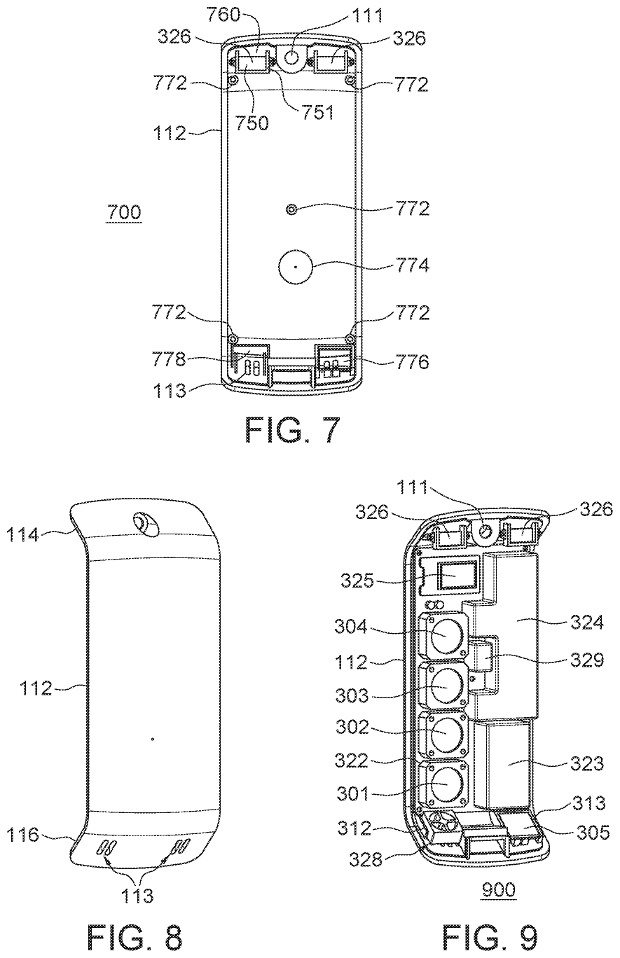

In some embodiments and referring to FIGS. 7-9, an assembly 700 can include the housing member 112 having a number of features including the screw or nail hole 111, a microphone port 774, a number of bosses 772 for enabling the mounting of the printed circuit board assembly 320 (see FIGS. 3-5) onto the housing member 112, a fan compartment 778 (similar to slot 312 of FIG. 3) and a temperature and humidity sensor PCB compartment 776 (similar to slot 313 of FIG. 3). The housing member 112 can further include one or more air ducts 326 that can be integrated and formed as part of the housing member 112 or alternatively separate duct members (such as the cup-like structures 326 of FIG. 3) that are fixed in position when the housing member 112 mates with the housing member 118. The air ducts or cup-like structures 326 could also be integrated as part of the housing member 118 (not shown).

In some embodiments and with further reference to FIGS. 7, 10 and 13, each air duct 326 includes an air entry port 760 and an air exit port 790, where airflow from within the housing is ushered toward the air entry port 760 of the air duct 326. The air duct 326 is positioned proximate the air exhaust port 117. The air duct 326 includes at least one wall 750, 751 defining the air entry port 760, the air exit port 790, and an air channel fluidly connecting and/or permitting airflow between the air entry port 760 and the air exit port 790. The air exit port 790 is aligned generally with the air exhaust port 117. The air entry port 760 is positioned closer to the top portion 114 of the housing than is the air exit port 790. The electronic circuitry is positioned within the housing between the bottom portion 116 of the housing and the air duct 326. In this configuration, the airflow is channeled upwards toward the top portion 114 of the housing, then down through the air entry port 760 of the air duct 326 and further down and out through the air exit port 790 of the air duct 326 (and out of the housing through the air exhaust port 117).

According to a further embodiment, the air duct 326 may be integrated into the sidewall 112, 118 of the housing such that the exit port 790 of the air duct 326 aligns with the air exhaust port 117. Additionally or alternatively, the air exhaust port 117 may be configured in the sidewall of the housing at a position at least two-thirds the length of the sidewall 112 as measured from an intersection of the sidewall 112 and the bottom portion 116 of the housing.

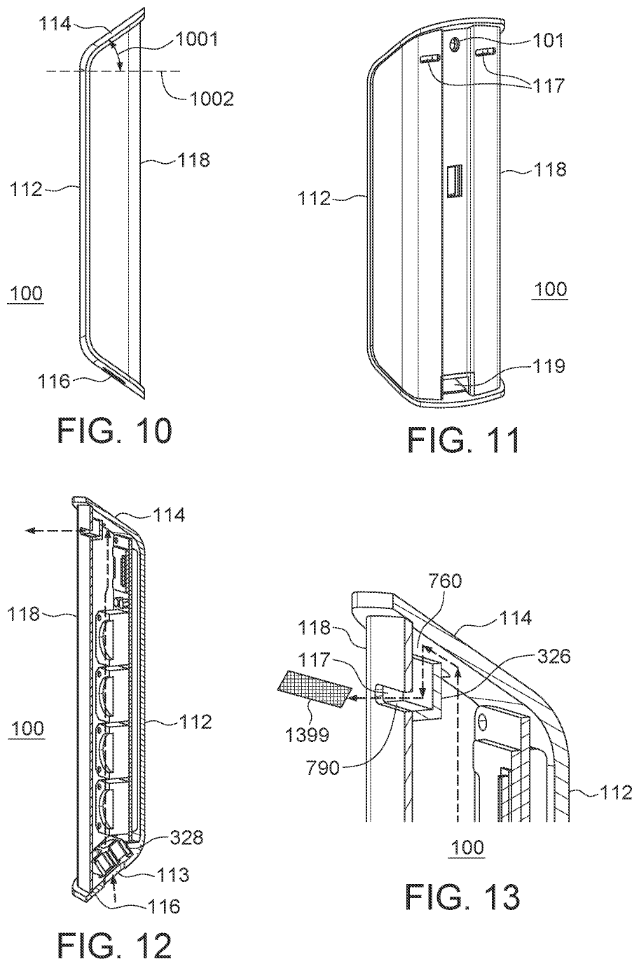

According to yet another embodiment, the top portion 114 of the housing may be slanted away from the sidewall 112 and the bottom portion 116 of the housing so as to channel airflow toward the air entry port 760 of the air duct 326. For example, with particular reference to FIG. 10, the top portion 114 of the housing may be slanted at an angle 1001 in a range of about 15 degrees to about 60 degrees relative to an axis 1002 orthogonal or perpendicular to the sidewall 112. Additionally or alternatively, the bottom portion 116 of the housing may be slanted away from the sidewall 112 and the top portion 114 of the housing.

According to a further embodiment, the electronic apparatus 100 may further include at least a second air exhaust port 117 (see FIG. 11) configured in a sidewall 118 of the housing and positioned between the bottom portion 116 of the housing and the top portion 114 of the housing. In such a case, the electronic apparatus may include at least a second air duct 326, where each air duct 326 is positioned inside the housing proximate a respective air exhaust port 117. In yet another embodiment, two or more air exhaust ports 117 may be configured in the same sidewall 118 of the housing. In a further embodiment, a hydrophobic mesh 1399 may be inserted within one or more of the air exhaust ports 117.

Referring to FIG. 8, a front perspective view of the housing member is shown illustrating the upwardly slanted top wall 114 and the downwardly slanted bottom wall 116. The downwardly slanted wall 116 can further include the one or more intake ports or vents 113. FIG. 9 further illustrates an assembly 900 than includes a populated substrate 322 mounted on the housing member 112 as well as structural features such as the cup-like shaped air ducts 326. The populated substrate 322 can have sensors and other components. As noted previously, the sensors and components can include an ozone sensor 304, a nitrous oxide sensor 303, a sulfur dioxide sensor 302, a carbon monoxide sensor 301, a particulate matter sensor 323, a connector 329, and a DALI module 325. The fan(s) 328 and external sensor 305 can be mounted off or separate from the substrate 322 and directly on the housing 112 in slot 312 (fan compartment 778) and slot 313 (T & H PCB Compartment 776) as shown in FIGS. 7 and 9.

In some embodiments and with reference to FIGS. 10-13, the electronic apparatus 10 includes a housing enclosure 112 having a top portion with a upwardly slanted top wall 114 where the at least one cup-like structure or air duct 326 forms a portion of a channel below the top portion or upwardly slanted top wall of the housing enclosure causing air flow to flow down from the upwardly slanted top wall and out of the at least one air exhaust port 117 where at least a portion of the channel (traversing from the air intake port 760 and out the air exit port 790 of the air duct 326) resides above a level of the at least one air exhaust port 117 which is near the top portion of the sidewalls of the apparatus. As noted previously, in some embodiments the at least one cup-like structure or air duct 326 is separate or can be integrally formed on an internal portion of the housing enclosure (either housing member 112 or housing member 118).

FIG. 10 illustrates a side view of the electronic apparatus 100 with the housing member 112 mated with the housing member 118. Further, this view illustrates the top portion of the housing with the upwardly slanted top wall 114 as well as a bottom portion having a downwardly sloping bottom wall 116. Although both sloping walls (114 and 116) can assist in ushering airflow up and out of the air exhaust port(s) 117, in some embodiments the sloping wall 116 at the bottom portion of the housing can be replaced with a non-sloping wall. As noted above, the top portion 114 of the housing may be slanted at an angle 1001 in a range of about 15 degrees to about 60 degrees relative to an axis 1002 orthogonal to the sidewall 112. This configuration assists with air flow and heat removal while mitigating water intrusion into the remainder of the housing. FIG. 11 illustrates a rear perspective view of the electronic apparatus 100 where the screw hole 101 and bracket hook feature 119 are clearly seen.

FIG. 12 is a side cut-view illustrating the air flow or air circulation path that comes in through the intake port 113 and up through the main housing and further deflecting off of the upwardly slanted top wall 114 and down and through the cup-like structure 326 and out the exhaust port 117. FIG. 13 provides an exploded view of the upper portion of the cut-view of FIG. 12 to more clearly illustrate the air circulation path. In certain instances, heated air pressure within the apparatus forces heated air against gravity and out of the exhaust ports 117. The cup-like structures or air ducts 326 may be optionally constructed on the inside of electronic apparatus 100 proximate to each air exhaust port 117 to further capture and contain any water intruding through the exhaust port 117 when apparatus is mounted in an exterior or outside environment. The hydrophobic mesh 1399 can optionally be mounted on or in the exhaust port to further mitigate moisture or water intrusion. One or more fans 328 may be optionally mounted inside the electronic apparatus 100 proximate the air intake port(s) 113 as shown in FIG. 12 to suck cool air in through air intake port(s) 113 and force such air over heat source(s) and toward the top of electronic apparatus 100. As further illustrated in FIGS. 7 and 13, the air duct or ducts 326 can include multiple walls 750, 751 or a single continuous wall and thereby support any cross-sectional geometry or configuration a particular housing may have. Furthermore, the air duct or ducts 326 provide an air entry port 760, an air exit port 790, and an air channel fluidly connecting and/or permitting air flow between the air entry port 760 and the air exit port 790.

In some embodiments and referring again to FIGS. 1-13, the electronic apparatus 100 is an environmental sensor apparatus having a housing enclosure having sidewalls on one or more housing enclosure members (112 and 118) including an upwardly slanted top wall 114 and a downwardly slanted bottom wall 116 on one of the one or more housing enclosure members, at least one air intake port 113 configured at a bottom portion 116 of the sidewalls, and at least one air exhaust port 117 configured near a top portion 114 of the sidewalls of the apparatus 100 where the housing enclosure is arranged and configured to force air from the at least one air intake port 113 and out the at least one air exhaust port 117. The environmental sensor apparatus can further include at least one channel structure (in the form of cup-like structures 326) arranged and constructed on an inside portion of the housing enclosure proximate the at least one air exhaust port 117 to capture and contain any moisture intruding through the housing enclosure where the channel structure includes a portion residing at a level above the at least one exhaust port 117. The channel structure is designed in this manner to reside above the level of the exhaust port so that any moisture that intrudes or collects generally within the cup-like structure 326 with the help of gravity. If the exhaust ports were formed at the very top of the housing enclosure, moisture intrusion may tend to intrude into areas beyond the cup-like structures. Thus, having the exhaust port reside below the channel structure (or put in another way, having the channel structure reside above the exhaust port) assists in the moisture mitigation function.

In some embodiments, the environmental sensor apparatus includes a plurality of environmental sensors mounted on a substrate 322 within the housing enclosure. In some embodiments, the substrate is a printed circuit board and the plurality of environmental sensors mounted on the substrate include any combination of two or more among a ozone sensor, a nitrous oxide sensor, a sulfur dioxide sensor, a carbon monoxide sensor, a particulate matter sensor, and a microphone. Of course, the embodiments are not limited to the sensors noted and other sensor combinations are certainly contemplated within the scope of the embodiments including cameras, infrared sensors, lights sensors, and any number of other sensors.

In some embodiments, the environmental sensor apparatus (100) includes at least one fan 328 to force air from the at least one air intake portion and out the at least one air exhaust port. In some embodiments, the at least one air exhaust port 117 includes at least two air exhaust ports and the at least one air intake ports 113 comprise at least two air intake portions.

In some embodiments, an environmental sensor apparatus (100) includes a housing enclosure having sidewalls including at least a top portion of the housing having an upwardly slanted top wall 114, at least two air intake ports 113 configured at a bottom portion 116 of the sidewalls, and at least two air exhaust ports 117 configured near the upwardly slanted top wall 114, where the housing enclosure is arranged and configured to force air from the at least two air intake ports 113 and out the at least two air exhaust ports 117. The environmental sensor apparatus can further include at least one channel structure arranged and constructed on an inside portion of the housing enclosure proximate the at two air exhaust ports 117 to capture and contain any moisture intruding through housing enclosure where the at least one channel structure includes a portion residing at a level above the at least one exhaust port.

In some embodiments with further reference to the module 140 of FIG. 14, the environmental sensor apparatus further includes a plurality of environmental sensors mounted on a substrate within the housing enclosure including at least a carbon monoxide sensor 301 and a particulate matter sensor 323. Other sensors can include, but are not limited to, any combination of a sulfur dioxide sensor 302, a nitrous oxide sensor 303, an ozone sensor 304, a pressure sensor 144, and a microphone 142.

In some embodiments, the environmental sensor apparatus (100) further includes at least one or more processors (see 145 in FIG. 14) mounted within a shielded portion (324) of the substrate and where the plurality environmental sensors reside on an unshielded portion of the module 140 (or assembly 320 of FIG. 3). In some embodiments the environmental sensor apparatus (100) can further include a communication module or transceiver 146 that enables wireless communication of data and control signals over one or any number of known wireless protocols (LTE, 5G, Wi-Fi, etc.).

The wireless transceiver module 146 may provide wireless communication capability to any one or more devices having corresponding wireless transceivers. In some cases, for example, using functionality provided by the wireless transceiver module 146, the electronic components embedded in a small cell device embodiment are arranged to operate as a Wi-Fi access point. In this way, the electronic components permit one or more mobile devices to access the internet. Municipalities or other entities may make internet services available over a determined geographic area (e.g., a neighborhood, a city, an arena, a construction site, a campus, or the like) to remote mobile devices that are in proximity to any one of a plurality of a number of embodiments incorporating the electronic components making up the electronic apparatus 100. For example, if many streetlight fixtures in a neighborhood or city are equipped with a small cell device, such as small cell device 100, then Wi-Fi service can be provided to a large number of users. Further, based on seamless communication between a plurality of small cell device embodiments, the Wi-Fi service can be configured as a mesh that permits users to perceive constant internet connectivity even when the mobile device is in motion.

In some embodiments, the fan 328 can be mounted on the module 140 rather than being mounted separately within the housing enclosure of the environmental sensor apparatus (100). In some embodiments fans 328 can reside both on the substrate 140 (or substrate assembly 320) and on the housing enclosure. In some embodiments, a fan can exist within the sensor components themselves that are mounted on the substrate. For example, an integrated fan can exist within the particulate matter (PM) sensor 323 ushering air through an intake in the PM sensor 323 and out an exhaust port in the PM sensor 323 where the air is further pushed upward toward the exhaust port of the environmental sensor apparatus (100). The external sensor 305 can be separate from the module 140 and include a temperature sensor and a humidity sensor for example. The external sensor can also optionally include its own fan. In some embodiments the environmental sensor apparatus further includes a temperature sensor and a humidity sensor mounted outside of the housing enclosure.

In some embodiments, the electronic apparatus can be a small cell device that monitors one or more sensors or conditions associated with a corresponding streetlight fixture for events. Examples of events can include, but are not limited to, light source failure (e.g., a burned-out bulb), light pole tilt, external vibrations, light source temperature, external temperature, power usage, images, motion detection, sound recordings, network traffic, network throughput, cellular signal strength, ambient light level, or other information that can be obtained or recorded by the small cell device that makes up the electronic apparatus 100.

The small cell device can be part of a system or network of streetlight poles, streetlight fixtures, streetlight sources, or the like in a system level deployment controlled by a municipality or other government agency. In other cases, the system controlled by a private entity (e.g., private property owner, third-party service contractor, or the like). In still other cases, a plurality of entities may share control of the system of streetlight poles streetlight fixtures, streetlight sources, or the like.

In other embodiments, each small cell device may be equipped with communication capabilities, which allows for the monitoring or remote control of a light source of the streetlight fixture or of another utility device. Accordingly, each light source in each streetlight fixture or in a broader context each device in any fixture can be monitored and controlled remotely independently or in combination. In the case of a streetlight fixture, each streetlight fixture can be monitored and/or controlled as an independent light source or in combination with other light sources where the electronic apparatus can serve to provide the wireless (or wired) communication of light control signals and any other information (e.g., packetized data) between small cell devices.

As one non-limiting, non-exhaustive example, each small cell device (100) may operate a small cell-networking device to provide wireless cellular-based network communication services. A mobile device provisioned by a mobile network operator or carrier can communicate with a small cell in the same or similar manner that a mobile device communicates with a macrocell tower. In at least some cases, an active communication session formed between a small cell and a mobile device may be handed-off to or from a small cell as the mobile device moves into or out from the active range of the small cell. For example, a user having an active communication session enabled by a small cell may be in motion, and when the mobile device is in motion, the active communication session may in some cases be automatically and seamlessly handed off and continue via another small cell or via a macrocell tower.

The electronic apparatus 100 embodied as a small cell-networking device can be integrated with a light fixture or a light pole and may be formed of any number of materials. The electronic apparatus 100 can be arranged as a networking device, but in other embodiments, the small cell device is a smart sensor device, a combination device, some other wireless networking device, or some other control device. In some embodiments, the light fixture can include a light source that can be an incandescent light source, a light emitting diode (LED) light source, a high pressure sodium lamp, or any other type of light source.

In some embodiments, the electronic apparatus 100 can be screwed and mounted on a planar surface using a screw through the screw hole and the bracket mount feature. In other instances, the electronic apparatus 100 can be mounted on a pole using a rotatable hinge and clamp such electronic apparatus does not restrict access to the interior components or access doors of a light fixture. Again, the electronic apparatus is not limited to attaching to a streetlight, but can attach to any number of objects including, but not limited to a light pole, an LED board, a bracket, a street sign, a highway sign, a bus stop shelter, an ATM, a phone booth, a building, an HVAC unit, a mailbox, a billboard, a light, a parking sign, a stop light, a speed limit sign, a solar cell, a crosswalk sign, a tunnel, a utility box, a water tower, a crane, a radio antenna tower, a store, an awning, a roof, or a parking pay station.

Note that references to “substrate” or “board” herein may refer to a circuit board, which may be a printed circuit board (PCB), including, without limitation, a single sided PCB, a double-sided PCB, a multilayer PCB, a rigid PCB, a flex PCB, or a rigid-flex PCB or a portion of a housing serving as a substrate. As is understood, any of the above circuit boards may include various electronic components coupled to, or carried by the circuit boards, including, for example, integrated circuits, integrated circuit chips or dies (including, without limitation, semiconductor chips or dies), wires, transistors, leadframes or pads, antennas, receivers, transmitters, transceivers, or other components. Moreover, each of the electronic components described above may be in electronic communication, either via wires (i.e., to transmit power or signals, among other functionality), or wirelessly to one or more of the other electronic components. Further, it is to be understood that any of the above can be coupled to one or more of the other electronic components of the small cell device 100 through one or more known coupling techniques or materials.

Moreover, in some cases, one or more internal or external antennas may be electrically and communicatively coupled to the small cell device 100 and integrated into, or mounted onto, various features of an external fixture such as a light pole. In some instances, one or more wires may extend through a light pole to communicatively and electrically couple the small cell device and the one or more antennas.

Further, it is to be appreciated that the present disclosure includes methods for forming a small cell, the forming including providing the electronic components in a housing enclosure suitable to be attached to any of the objects describe herein and other like objects, installing the small cell device, and connecting the small cell device to a power source or other utility line to pass power and data via one or more wires or cables or via a wireless communication channel.

In the absence of any specific clarification related to its express use in a particular context, where the terms “substantial” or “about” in any grammatical form are used as modifiers in the present disclosure and any appended claims (e.g., to modify a structure, a dimension, a measurement, or some other characteristic), it is understood that the characteristic may vary by up to 30 percent. For example, a small cell networking device may be described as being mounted “substantially vertical,” In these cases, a device that is mounted exactly vertical is mounted along a “Y” axis and a “X” axis that is normal (i.e., 90 degrees or at a right angle) to a plane or line formed by a “Z” axis. Different from the exact precision of the term, “vertical,” and the use of “substantially” or “about” to modify the characteristic permits a variance of the particular characteristic by up to 30 percent.

The terms “include” and “comprise,” as well as derivatives thereof in all of their syntactic contexts, are to be construed without limitation in an open, inclusive sense (e.g., “including, but not limited to”). The term “or” is inclusive, meaning “and or.” The phrases “associated with” and “associated therewith,” as well as derivatives thereof, can be understood as meaning to include, be included within, interconnect with, contain, be contained within, connect to or with, couple to or with, be communicable with, cooperate with, interleave, juxtapose, be proximate to, be bound to or with, have, have a property of, or the like.

Unless the context requires otherwise, throughout the specification and claims which follow, the word “comprise” and variations thereof, such as “comprises” and “comprising,” are to be construed in an open, inclusive sense (e.g., including, but not limited to).

Reference throughout this specification to “one embodiment” or “an embodiment” or “some embodiments” and variations thereof means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content and context clearly dictates otherwise. It should also be noted that the conjunctive terms, “and” and “or” are generally employed in the broadest sense to include “and/or” unless the content and context clearly dictates inclusivity or exclusivity as the case may be. In addition, the composition of “and” and “or” when recited herein as “and/or” is intended to encompass an embodiment that includes all of the associated items or ideas and one or more other alternative embodiments that include fewer than all of the associated items or idea.

As the context may require in this disclosure, except as the context may dictate otherwise, the singular shall mean the plural and vice versa. All pronouns shall mean and include the person, entity, firm or corporation to which they relate. Also, the masculine shall mean the feminine and vice versa.

When so arranged as described herein, each computing device may be transformed from a generic and unspecific computing device to a combination device comprising hardware and software configured for a specific and particular purpose. When so arranged as described herein, to the extent that any of the inventive concepts described herein are found by a body of competent adjudication to be subsumed in an abstract idea, the ordered combination of elements and limitations are expressly presented to provide a requisite inventive concept by transforming the abstract idea into a tangible and concrete practical application of that abstract idea.

The various embodiments described above can be combined to provide further embodiments. Aspects of the embodiments can be modified, if necessary to employ concepts of the various patents, application and publications to provide yet further embodiments.

What is claimed is:

1. An electronic apparatus comprising:
a housing having a top portion, a bottom portion, and one or more sidewalls, the one or more sidewalls interconnecting the top portion and the bottom portion;
at least one air intake port configured in the bottom portion of the housing;
an air exhaust port configured in a sidewall of the housing and positioned between the bottom portion of the housing and the top portion of the housing;
an air duct positioned inside the housing proximate the air exhaust port, the air duct including at least one wall defining an air entry port and an air exit port, the air exit port being aligned generally with the air exhaust port, the air entry port being positioned closer to the top portion of the housing than is the air exit port; and
electronic circuitry positioned within the housing between the bottom portion of the housing and the air duct.

2. The electronic apparatus of claim 1, further comprising at least one fan operable to force air from the at least one air intake port toward the top portion of the housing.

3. The electronic apparatus of claim 1, further comprising one or more sensors mounted on the housing.

4. The electronic apparatus of claim 1, further comprising:
a second air exhaust port configured in a sidewall of the housing and positioned between the bottom portion of the housing and the top portion of the housing; and
a second air duct positioned inside the housing proximate the second air exhaust port, the second air duct including at least one wall defining a second air entry port and a second air exit port, the second air exit port being aligned generally with the second air exhaust port, the second air entry port being positioned closer to the top portion of the housing than is the second air exit port.

5. The electronic apparatus of claim 4, wherein the sidewall in which the second air exhaust port is configured and the sidewall in which the air exhaust port is configured are the same.

6. The electronic apparatus of claim 1, wherein the electronic circuitry includes at least a plurality of environmental sensors.

7. The electronic apparatus of claim 6, wherein the electronic circuitry further includes a digital addressable lighting interface module.

8. The electronic apparatus of claim 1, wherein the air duct is integrated into the sidewall of the housing such that the exit port of the air duct aligns with the air exhaust port.

9. The electronic apparatus of claim 1, wherein the sidewall has a length and a width, wherein the length of the sidewall is greater than the width of the sidewall, and wherein the air exhaust port is configured in the sidewall at a position at least two-thirds the length of the sidewall as measured from an intersection of the sidewall and the bottom portion of the housing.

10. The electronic apparatus of claim 1, further comprising a hydrophobic mesh inserted within the air exhaust port.

11. The electronic apparatus of claim 1, wherein the top portion of the housing is slanted away from the sidewall and the bottom portion of the housing so as to channel airflow toward the air entry port of the air duct.

12. The electronic apparatus of claim 11, wherein the top portion of the housing is slanted at an angle in a range of about 15 degrees to about 60 degrees relative to an axis orthogonal to the sidewall.

13. The electronic apparatus of claim 1, wherein the bottom portion of the housing is slanted away from the sidewall and the top portion of the housing.

14. An electronic apparatus comprising:
a housing having a slanted top portion, a bottom portion, and one or more sidewalls, the one or more sidewalls interconnecting the top portion and the bottom portion;
at least one air intake port configured in the bottom portion of the housing;
an air exhaust port configured in a sidewall of the housing and positioned between the bottom portion of the housing and the top portion of the housing;
an air duct integrated into an inside surface of the sidewall of the housing proximate the air exhaust port, the air duct including at least one wall defining an air entry port and an air exit port, the air exit port being aligned with the air exhaust port, the air entry port being positioned closer to the top portion of the housing than is the air exit port; and
electronic circuitry positioned within the housing between the bottom portion of the housing and the air duct.

15. The electronic apparatus of claim 14, further comprising at least one fan operable to force air from the at least one air intake port toward the top portion of the housing.

16. The electronic apparatus of claim 14, further comprising:
a second air exhaust port configured in the sidewall of the housing and positioned between the bottom portion of the housing and the top portion of the housing; and
a second air duct integrated into the inside surface of the sidewall of the housing proximate the second air exhaust port, the second air duct including at least one wall defining a second air entry port and a second air exit port, the second air exit port being aligned with the second air exhaust port, the second air entry port being positioned closer to the top portion of the housing than is the second air exit port.

17. The electronic apparatus of claim 14, wherein the electronic circuitry includes a plurality of environmental sensors.

18. The electronic apparatus of claim 14, wherein the top portion of the housing is slanted at an angle in a range of about 15 degrees to about 60 degrees relative to an axis orthogonal to the sidewall.

19. An electronic apparatus comprising:
a housing enclosure having a top portion, a bottom portion, and one or more sidewalls, the one or more sidewalls interconnecting the top portion and the bottom portion;
at least two air intake ports configured in the bottom portion of the housing;
at least two air exhaust ports configured in a sidewall of the housing and positioned between the bottom portion of the housing and the top portion of the housing;
at least two air ducts located inside the housing, each air duct being positioned proximate a respective air exhaust port of the at two air exhaust ports and including at least one wall defining an air entry port and an air exit port, the air exit port of the air duct being aligned generally with the respective air exhaust port, the air entry port of the air duct being positioned closer to the top portion of the housing than is the air exit port of the air duct; and
electronic circuitry positioned within the housing between the bottom portion of the housing and the at least two air ducts.

20. The electronic apparatus of claim 19, wherein the top portion of the housing is slanted away from the sidewall and the bottom portion of the housing so as to channel airflow toward air entry ports of the at least two air ducts.
